(19) United States
(12) Patent Application Publication
(10) Pub. No.: US 2025/0308600 A1
(43) Pub. Date: Oct. 2, 2025

(54) DISCHARGE CIRCUITS

(71) Applicant: MICRON TECHNOLOGY, INC., BOISE, ID (US)

(72) Inventors: Kenneth W. Marr, Boise, ID (US); James E. Davis, Meridian, ID (US); Chiara Cerafogli, Boise, ID (US)

(73) Assignee: MICRON TECHNOLOGY, INC., BOISE, ID (US)

(21) Appl. No.: 19/235,850

(22) Filed: Jun. 12, 2025

Related U.S. Application Data
(62) Division of application No. 17/897,448, filed on Aug. 29, 2022, now Pat. No. 12,354,669.

(51) Int. Cl. G11C 16/22; G11C 16/04; G11C 16/16

(52) U.S. Cl. CPC G11C 16/22; G11C 16/0483; G11C 16/16

(57) ABSTRACT

A discharge circuit includes a transistor and a metal resistor connected to the transistor. The transistor includes a plurality of unit cells. The metal resistor includes a plurality of resistor portions corresponding to the plurality of unit cells. Each unit cell of the plurality of unit cells has a footprint and a corresponding resistor portion of the plurality of resistor portions is arranged within the footprint.

### RELATED APPLICATION

This Application is a Divisional of U.S. application Ser. No. 17/897,448 titled “DISCHARGE CIRCUITS,” filed Aug. 29, 2022, (Allowed) which is commonly assigned and incorporated herein by reference.

### TECHNICAL FIELD

The present disclosure relates generally to discharge circuits and, in particular, in one or more embodiments, the present disclosure relates to discharge circuits for high-voltage, high-capacitance nets.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. Each source select transistor may be connected to a source, while each drain select transistor may be connected to a data line, such as column bit line. Variations using more than one select gate between a string of memory cells and the source, and/or between the string of memory cells and the data line, are known.

A source in a NAND flash memory might be both high-voltage (e.g., greater than 15V) and high-capacitance (e.g., greater than 1 nF). During operation of the NAND flash memory, a source might need to be charged and discharged. During discharging of the source, the flash memory should remain in a safe operating area (SOA) and snapback should be avoided to prevent damage to the flash memory.

### BRIEF DESCRIPTION OF THE DRAWINGS

FIGS. 1A-1C are simplified schematic diagrams of discharge circuits according to various embodiments.

FIGS. 2A-2C are schematic diagrams of unit cells of a transistor of the discharge circuits of FIGS. 1A-1C, respectively, according to various embodiments.

FIG. 3 is a schematic layout diagram of a unit cell of a transistor and a resistor portion of a discharge circuit according to an embodiment.

FIG. 4 is a schematic diagram of a discharge circuit according to another embodiment.

FIG. 5 is a schematic layout diagram of two banks of unit cells of a discharge circuit according to an embodiment.

FIG. 6 is a simplified block diagram of a memory device including a discharge circuit according to an embodiment.

FIG. 7 is a chart illustrating the operation of a discharge circuit according to an embodiment.

FIG. 8 is a schematic diagram of a portion of an array of memory cells according to an embodiment.

FIG. 9 is a flow diagram illustrating a method for performing an erase operation on an array of memory cells according to an embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments may be utilized and structural, logical and electrical changes may be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by an electrically conductive path unless otherwise apparent from the context.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

A discharge circuit for discharging a high-voltage (e.g., greater than 15V), high-capacitance (e.g., greater than 1 nF) net (e.g., node) in an integrated circuit might include a plurality of high-voltage transistors (e.g., 3 to 6 transistors) connected in a voltage stepdown configuration (e.g., in series). To improve performance and reduce area compared to a discharge circuit connected in a voltage stepdown configuration, the discharge circuits disclosed herein include a single high-voltage transistor with an embedded area-neutral metal resistor while addressing safe operating area (SOA) and snapback concerns. The disclosed discharge circuits might have improved performance compared to discharge circuits connected in a voltage stepdown configuration since the removal of the series devices increases conductance. The disclosed discharge circuits might also occupy a reduced area since removal of the series devices decreases area consumption. Snapback/aging might be mitigated within the disclosed discharge circuits via an adjustable negative-feedback source resistance and/or an adjustable drain resistance. Snapback might also be mitigated within the disclosed discharge circuits by applying a stepped control signal to the discharge circuits so that the discharge circuits remain in a safe operating area. The resistance of each unit cell of the high-voltage transistor of the discharge circuits might be individually tuned for each unit cell. The transistor width of each unit cell might be aligned with an area-neutral embedded resistor portion of the metal resistor. Thus, the discharge circuits disclosed herein might enable a smaller discharge circuit compared to discharge circuits connected in a voltage stepdown configuration, thereby enabling a die-size reduction and/or a faster discharge circuit for improved performance.

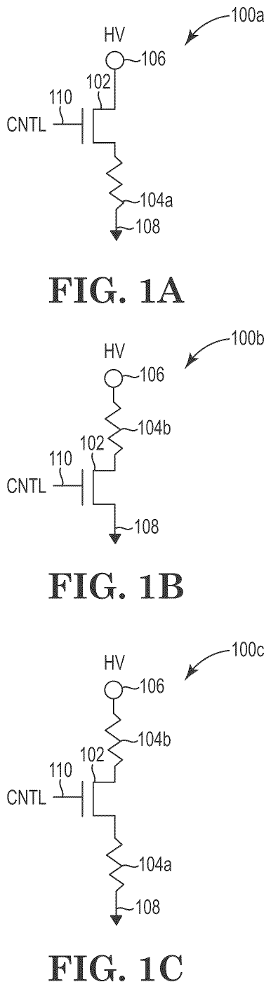

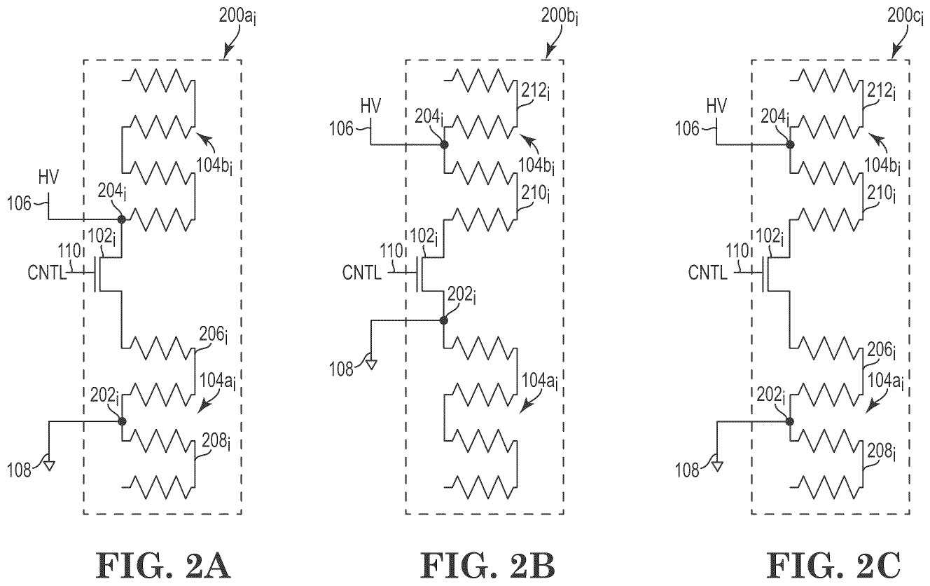

FIG. 1A is a simplified schematic diagram of a discharge circuit 100a according to an embodiment. Discharge circuit 100a includes a high-voltage transistor 102 and a metal resistor 104a connected to the transistor 102. The transistor 102 might be an N-channel high-voltage metal-oxide-semiconductor field-effect transistor (MOSFET) (e.g., a NMOS transistor or a triple well NMOS transistor) including a plurality of unit cells. One side of the source-drain path (e.g., drain) of the transistor 102 might be connected to a high-voltage (HV) node 106. The other side of the source-drain path (e.g., source) of the transistor 102 might be connected to one side of the metal resistor 104a. The other side of the metal resistor 104a might be connected to a reference voltage node 108 (e.g., a common or ground node). The gate of the transistor 102 might be connected to a control (CNTL) signal node 110. As described below with reference to FIGS. 2A-2C, the metal resistor 104a might include a plurality of resistor portions corresponding to the plurality of unit cells of the transistor 102. Each unit cell of the plurality of unit cells has a footprint and a corresponding resistor portion of the plurality of resistor portions might be arranged within the footprint.

Discharge circuit 100a might discharge the voltage on the high-voltage node 106 in response to a control signal on the control signal node 110. In response to a sufficient control signal (e.g., voltage level) on the control signal node 110, the discharge circuit 100a is enabled, transistor 102 is turned on (e.g., conducting), and high-voltage node 106 is discharged through the metal resistor 104a to the reference voltage node 108. In response to no control signal (e.g., 0V) on the control signal node 110, the discharge circuit 100a is disabled, transistor 102 is turned off (e.g., not conducting), and high-voltage node 106 is not discharged through the metal resistor 104a.

FIG. 1B is a simplified schematic diagram of a discharge circuit 100b according to another embodiment. Discharge circuit 100b includes a high-voltage transistor 102 as previously described above with reference to FIG. 1A and a metal resistor 104b connected to the transistor 102. One side of the source-drain path (e.g., drain) of the transistor 102 might be connected to one side of the metal resistor 104b. The other side of the metal resistor 104b might be connected to a high-voltage (HV) node 106. The other side of the source-drain path (e.g., source) of the transistor 102 might be connected to a reference voltage node 108. The gate of the transistor 102 might be connected to a control (CNTL) signal node 110. As described below with reference to FIGS. 2A-2C, the metal resistor 104b might include a plurality of resistor portions corresponding to the plurality of unit cells of the transistor 102. Each unit cell of the plurality of unit cells has a footprint and a corresponding resistor portion of the plurality of resistor portions might be arranged within the footprint.

Discharge circuit 100b might discharge the voltage on the high-voltage node 106 in response to a control signal on the control signal node 110. In response to a sufficient control signal (e.g., voltage level) on the control signal node 110, the discharge circuit 100b is enabled, transistor 102 is turned on (e.g., conducting), and high-voltage node 106 is discharged through the metal resistor 104b to the reference voltage node 108. In response to no control signal (e.g., 0V) on the control signal node 110, the discharge circuit 100b is disabled, transistor 102 is turned off (e.g., not conducting), and high-voltage node 106 is not discharged through the metal resistor 104b.

FIG. 1C is a simplified schematic diagram of a discharge circuit 100c according to another embodiment. Discharge circuit 100c includes a high-voltage transistor 102 as previously described above with reference to FIG. 1A and a metal resistor 104a/104b connected to the transistor 102. In this embodiment, the metal resistor includes a first segment 104a and a second segment 104b. One side of the source-drain path (e.g., source) of the transistor 102 might be connected to one side of the first segment 104a of the metal resistor. The other side of the first segment 104a of the metal resistor might be connected to a reference voltage node 108. The other side of the source-drain path (e.g., drain) of the transistor 102 might be connected to one side of the second segment 104b of the metal resistor. The other side of the second segment 104b of the metal resistor might be connected to a high-voltage (HV) node 106. The gate of transistor 102 might be connected to a control (CNTL) signal node 110. As described below with reference to FIGS. 2A-2C, the metal resistor 104a/104b might include a plurality of resistor portions corresponding to the plurality of unit cells of the transistor 102. Each unit cell of the plurality of unit cells has a footprint and a corresponding resistor portion of the plurality of resistor portions might be arranged within the footprint.

Discharge circuit 100c might discharge the voltage on high-voltage node 106 in response to a control signal on the control signal node 110. In response to a sufficient control signal (e.g., voltage level) on the control signal node 110, the discharge circuit 100c is enabled, transistor 102 is turned on (e.g., conducting), and high-voltage node 106 is discharged through the second segment 104b and the first segment 104a of the metal resistor to the reference voltage node 108. In response to no control signal (e.g., 0V) on the control signal node 110, the discharge circuit 100c is disabled, transistor 102 is turned off (e.g., not conducting), and high-voltage node 106 is not discharged through the second segment 104b and the first segment 104a of the metal resistor.

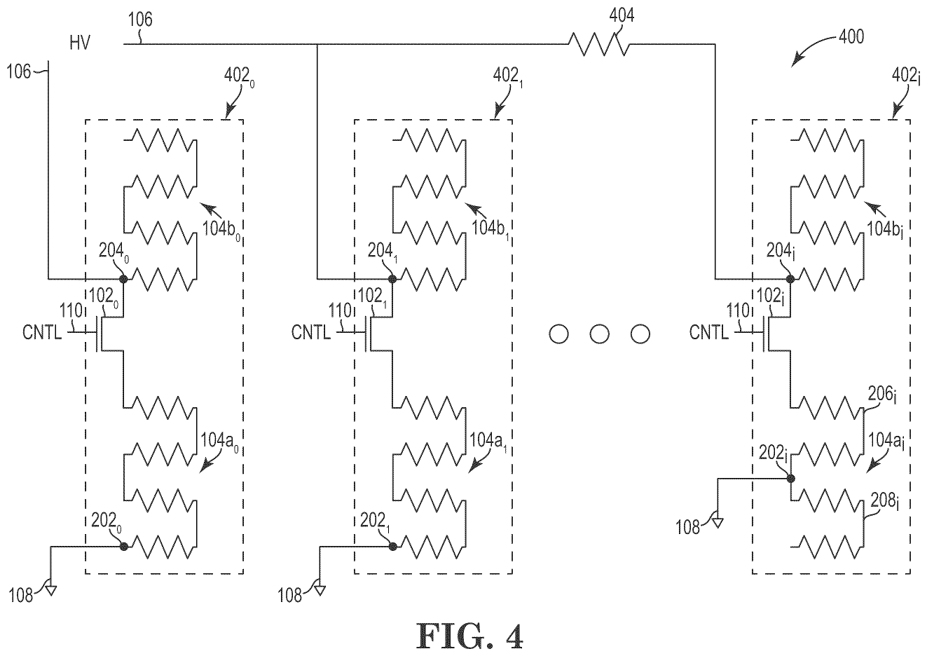

FIG. 2A is a schematic diagram of one unit cell 200aᵢ of a transistor 102 according to an embodiment. A plurality of unit cells 200a₀ to 200aᵢ of transistor 102 may be connected in parallel (as described below with reference to FIG. 4) to provide discharge circuit 100a previously described and illustrated with reference to FIG. 1A, where “i” is any suitable number (e.g., 2 to 15). Each unit cell 200aᵢ includes a transistor finger 102ᵢ and a metal resistor portion 104aᵢ/104bᵢ. The metal resistor portion includes a first segment 104aᵢ and a second segment 104bᵢ. The first segment 104aᵢ might be directly connected to one side of the source-drain path (e.g., source) of the transistor finger 102ᵢ, and the second segment 104bᵢ might be directly connected to the other side of the source-drain path (e.g., drain) of the transistor finger 102ᵢ. The gate of the transistor finger 102ᵢ might be connected to a control signal node 110.

Unit cell 200aᵢ also includes a first contact 202ᵢ and a second contact 204ᵢ. The first contact 202ᵢ might be connected to the first segment 104aᵢ to connect one side of the source-drain path (e.g., source) of the transistor finger 102ᵢ to a reference voltage node 108. In this embodiment, the first contact 202ᵢ might be connected to the first segment 104aᵢ such that a first part of the first segment 104aᵢ as indicated at 206ᵢ might be connected between the first contact 202ᵢ and one side of the source-drain path (e.g., source) of the transistor finger 102ᵢ and a second part of the first segment 104aᵢ as indicated at 208ᵢ might be floating. The point along the first segment 104aᵢ where the first contact 202ᵢ is connected may be adjusted to adjust the resistance connected between the first contact 202ᵢ and one side of the source-drain path (e.g., source) of the transistor finger 102ᵢ. In other embodiments, the first contact 202ᵢ might be connected to the end of the first segment 104aᵢ such that the entire first segment 104aᵢ is connected between the first contact 202ᵢ and one side of the source-drain path (e.g., source) of the transistor finger 102ᵢ and none of the first segment 104aᵢ is floating.

The second contact 204ᵢ might be connected to the second segment 104bᵢ to connect the other side of the source-drain path (e.g., drain) of the transistor finger 102ᵢ to a high-voltage node 106 connected to a circuit to be discharged. In this embodiment, the second contact 204ᵢ might be connected to the second segment 104bᵢ such that the second segment 104bᵢ is floating. That is, the second contact 204ᵢ might be directly connected to one side of the source-drain path (e.g., drain) of the transistor finger 102ᵢ such that the entire second segment 104bᵢ is floating.

FIG. 2B is a schematic diagram of one unit cell 200bᵢ of a transistor 102 according to another embodiment. A plurality of unit cells 200b₀ to 200bᵢ of transistor 102 may be connected in parallel (as described below with reference to FIG. 4) to provide discharge circuit 100b previously described and illustrated with reference to FIG. 1B. Each unit cell 200bᵢ includes a transistor finger 102ᵢ and a metal resistor portion 104aᵢ/104bᵢ. The metal resistor portion includes a first segment 104aᵢ and a second segment 104bᵢ. The first segment 104aᵢ might be directly connected to one side of the source-drain path (e.g., source) of the transistor finger 102ᵢ, and the second segment 104bᵢ might be directly connected to the other side of the source-drain path (e.g., drain) of the transistor finger 102ᵢ. The gate of the transistor finger 102ᵢ might be connected to a control signal node 110.

Unit cell 200bᵢ also includes a first contact 202ᵢ and a second contact 204ᵢ. The first contact 202ᵢ might be connected to the first segment 104aᵢ to connect one side of the source-drain path (e.g., source) of the transistor finger 102ᵢ to a reference voltage node 108. In this embodiment, the first contact 202ᵢ might be connected to the first segment 104aᵢ such that first segment 104aᵢ is floating. That is, the first contact 202ᵢ might be directly connected to one side of the source-drain path (e.g., source) of the transistor finger 102ᵢ such that the entire first segment 104aᵢ is floating.

The second contact 204ᵢ might be connected to the second segment 104bᵢ to connect the other side of the source-drain path (e.g., drain) of the transistor finger 102ᵢ to a high-voltage node 106 connected to a circuit to be discharged. In this embodiment, the second contact 204ᵢ might be connected to the second segment 104bᵢ such that a first part of the second segment 104bᵢ as indicated at 210ᵢ might be connected between the second contact 204ᵢ and one side of the source-drain path (e.g., drain) of the transistor finger 102ᵢ and a second part of the second segment 104bᵢ as indicated at 212ᵢ might be floating. The point along second segment 104bᵢ where the second contact 204ᵢ is connected may be adjusted to adjust the resistance connected between the second contact 204ᵢ and one side of the source-drain path (e.g., drain) of the transistor finger 102ᵢ. In other embodiments, the second contact 204ᵢ might be connected to the end of the second segment 104bᵢ such that the entire second segment 104bᵢ is connected between the second contact 204ᵢ and one side of the source-drain path (e.g., drain) of the transistor finger 102ᵢ and none of the second segment 104bᵢ is floating.

FIG. 2C is a schematic diagram of one unit cell 200cᵢ of a transistor 102 according to another embodiment. A plurality of unit cells 200c₀ to 200cᵢ of transistor 102 may be connected in parallel (as described below with reference to FIG. 4) to provide discharge circuit 100c previously described and illustrated with reference to FIG. IC. Each unit cell 200cᵢ includes a transistor finger 102ᵢ and a metal resistor portion 104aᵢ/104bᵢ. The metal resistor portion includes a first segment 104aᵢ and a second segment 104bᵢ. The first segment 104aᵢ might be directly connected to one side of the source-drain path (e.g., source) of the transistor finger 102ᵢ, and the second segment 104bᵢ might be directly connected to the other side of the source-drain path (e.g., drain) of the transistor finger 102ᵢ. The gate of the transistor finger 102ᵢ might be connected to a control signal node 110.

Unit cell 200cᵢ also includes a first contact 202ᵢ and a second contact 204ᵢ. The first contact 202ᵢ might be connected to the first segment 104aᵢ to connect one side of the source-drain path (e.g., source) of the transistor finger 102ᵢ to a reference voltage node 108. In this embodiment, the first contact 202ᵢ might be connected to the first segment 104aᵢ such that a first part of the first segment 104aᵢ as indicated at 206ᵢ might be connected between the first contact 202ᵢ and one side of the source-drain path (e.g., source) of the transistor finger 102ᵢ and a second part of the first segment 104aᵢ as indicated at 208ᵢ might be floating. The point along first segment 104aᵢ where the first contact 202ᵢ is connected may be adjusted to adjust the resistance connected between the first contact 202ᵢ and one side of the source-drain path (e.g., source) of the transistor finger 102ᵢ. In other embodiments, the first contact 202ᵢ might be connected to the end of the first segment 104aᵢ such that the entire first segment 104aᵢ is connected between the first contact 202ᵢ and one side of the source-drain path (e.g., source) of the transistor finger 102i and none of the first segment 104aᵢ is floating.

The second contact 204ᵢ is connected to the second segment 104bᵢ to connect the other side of the source-drain path (e.g., drain) of the transistor finger 102ᵢ to a high-voltage node 106 connected to a circuit to be discharged. In this embodiment, the second contact 204ᵢ might be connected to the second segment 104bᵢ such that a first part of the second segment 104bᵢ as indicated at 210ᵢ might be connected between the second contact 204ᵢ and one side of the source-drain path (e.g., drain) of the transistor finger 102ᵢ and a second part of the second segment 104bᵢ as indicated at 212ᵢ might be floating. The point along second segment 104bᵢ where the second contact 204ᵢ is connected may be adjusted to adjust the resistance connected between the second contact 204ᵢ and one side of the source-drain path (e.g., drain) of the transistor finger 102ᵢ. In other embodiments, the second contact 204ᵢ might be connected to the end of the second segment 104bᵢ such that the entire second segment 104bᵢ is connected between the second contact 204ᵢ and one side of the source-drain path (e.g., drain) of the transistor finger 102ᵢ and none of the second segment 104bᵢ is floating.

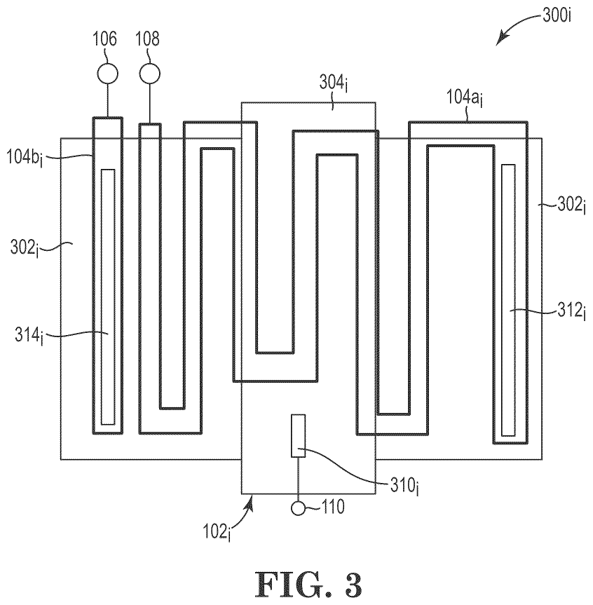

FIG. 3 is a schematic layout diagram of a unit cell 300ᵢ of a transistor 102 according to an embodiment. A plurality of unit cells 300₀ to 300ᵢ of the transistor 102 may be connected in parallel to provide a discharge circuit, such as discharge circuit 100a, 100b, or 100c as previously described and illustrated with reference to FIGS. 1A-1C. Each unit cell 300ᵢ might include a transistor finger 102ᵢ including an active region 302ᵢ and a polysilicon region 304ᵢ, contacts 310ᵢ, 312ᵢ, and 314ᵢ, and a metal resistor portion 104aᵢ/104bᵢ. The metal resistor portion includes a first segment 104aᵢ and a second segment 104bᵢ. The active region 302ᵢ defines a source and a drain of the transistor finger 102ᵢ. The polysilicon region 304ᵢ defines a gate of the transistor finger 102ᵢ.

Contact 310ᵢ might be a gate contact to connect the gate of the transistor finger 102ᵢ to a control signal node 110. Contact 310ᵢ might be a vertical contact to connect the gate of the transistor finger 102ᵢ in a lower layer of a semiconductor integrated circuit to the control signal node 110 in an upper layer of the semiconductor integrated circuit. Contact 312ᵢ might be a source contact to connect the source of the transistor finger 102ᵢ to the first segment 104aᵢ of the metal resistor portion. The first segment 104aᵢ might also be connected to a reference voltage node 108. Contact 312ᵢ might be a vertical contact to connect the source of the transistor finger 102ᵢ in a lower layer of the semiconductor integrated circuit to the first segment 104aᵢ in an upper layer of the semiconductor integrated circuit. Contact 314ᵢ might be a drain contact to connect the drain of the transistor finger 102ᵢ to the second segment 104bᵢ of the metal resistor portion. The second segment 104bᵢ might also be connected to a high-voltage node 106. Contact 314ᵢ might be a vertical contact to connect the drain of the transistor finger 102ᵢ in a lower layer of the semiconductor integrated circuit to the second segment 104bᵢ in an upper layer of the semiconductor integrated circuit.

As illustrated in FIG. 3, the unit cell 300ᵢ has a footprint and the resistor portion 104aᵢ/104bᵢ is arranged within the footprint. In this example, the first segment 104aᵢ might include a relatively long metal (e.g., tungsten) trace (and corresponding relatively higher resistance) including a plurality of trace segments arranged in a zigzag or serpentine arrangement, while second segment 104bᵢ might include a relatively short metal (e.g., tungsten) trace (and corresponding relatively lower resistance) having a single trace segment arranged in a line. In other examples, first segment 104aᵢ might include a metal trace having a different length (and corresponding different resistance) and may include a different number of trace segments arranged in a zigzag or serpentine arrangement or a single trace segment arranged in a line, while second segment 104bᵢ might include a metal trace having a different length (and corresponding different resistance) and may include a plurality of trace segments arranged in a zigzag or serpentine arrangement. Accordingly, first segment 104aᵢ and second segment 104bᵢ might be arranged to set the desired resistance of first segment 104aᵢ and second segment 104bᵢ, respectively.

FIG. 4 is a schematic diagram of a discharge circuit 400 according to another embodiment. Discharge circuit 400 includes a transistor 102 including a plurality of unit cells 402₀ to 402ᵢ. Discharge circuit 400 also includes a metal resistor 104a/104b connected to the transistor 102. The metal resistor includes a plurality of resistor portions 104a₀/104b₀ to 104aᵢ/104bᵢ corresponding to the plurality of unit cells 402₀ to 402ᵢ, respectively. As previously described, each unit cell 402₀ to 402ᵢ has a footprint and a corresponding resistor portion 104a₀/104b₀ to 104aᵢ/104bᵢ is arranged within the footprint. The plurality of unit cells 402₀ to 402ᵢ of transistor 102 are connected in parallel.

Unit cell 402₀ includes a transistor finger 102₀ and a metal resistor portion 104a₀/104b₀. The metal resistor portion includes a first segment 104a₀ and a second segment 104b₀. The first segment 104a₀ might be directly connected to one side of the source-drain path (e.g., source) of the transistor finger 102₀, and the second segment 104b₀ might be directly connected to the other side of the source-drain path (e.g., drain) of the transistor finger 102₀. The gate of the transistor finger 102₀ might be connected to a control signal node 110. Unit cell 402₀ also includes a first contact 202₀ and a second contact 204₀. The first contact 202₀ might be connected to the first segment 104a₀ to connect one side of the source-drain path (e.g., source) of the transistor finger 102₀ to a reference voltage node 108. In this embodiment, the first contact 202₀ might be connected to the first segment 104a₀ such that the entire first segment 104a₀ is connected between the first contact 202₀ and one side of the source-drain path (e.g., source) of the transistor finger 102₀. The second contact 204₀ might be connected to the second segment 104b₀ to connect the other side of the source-drain path (e.g., drain) of the transistor finger 102₀ to a high-voltage node 106 connected to a circuit to be discharged. In this embodiment, the second contact 204₀ might be connected to the second segment 104b₀ such that the entire second segment 104b₀ is floating.

Likewise, unit cell 402₁ includes a transistor finger 102₁ and a metal resistor portion 104a₁/104b₁. The metal resistor portion includes a first segment 104a₁ and a second segment 104b₁. The first segment 104a₁ might be directly connected to one side of the source-drain path (e.g., source) of the transistor finger 102₁, and the second segment 104b₁ might be directly connected to the other side of the source-drain path (e.g., drain) of the transistor finger 102₁. The gate of the transistor finger 102₁ might be connected to the control signal node 110. Unit cell 402₁ also includes a first contact 202₁ and a second contact 204₁. The first contact 202₁ might be connected to the first segment 104a₁ to connect one side of the source-drain path (e.g., source) of the transistor finger 102₁ to the reference voltage node 108. In this embodiment, the first contact 202₁ might be connected to the first segment 104a₁ such that the entire first segment 104a₁ is connected between the first contact 202₁ and one side of the source-drain path (e.g., source) of the transistor finger 102₁. The second contact 204₁ might be connected to the second segment 104b₁ to connect the other side of the source-drain path (e.g., drain) of the transistor finger 102₁ to the high-voltage node 106 connected to the circuit to be discharged. In this embodiment, the second contact 204₁ might be connected to the second segment 104b₁ such that the entire second segment 104b₁ is floating.

The high-voltage node 106 might include a resistance 404 (e.g., parasitic resistance) along its length such that without compensation by discharge circuit 400, different currents might be discharged through one or more of the unit cells 402₀ to 402ᵢ resulting in imbalance. Thus, to equalize the current discharged through each unit cell 402₀ to 402ᵢ, the resistance of one or more unit cells affected by the resistance 404 might be reduced as indicated for example by unit cell 402ᵢ.

Each unit cell 402ᵢ includes a transistor finger 102ᵢ and a metal resistor portion 104aᵢ/104bᵢ. The metal resistor portion includes a first segment 104aᵢ and a second segment 104bᵢ. The first segment 104aᵢ might be directly connected to one side of the source-drain path (e.g., source) of the transistor finger 102ᵢ, and the second segment 104bᵢ might be directly connected to the other side of the source-drain path (e.g., drain) of the transistor finger 102ᵢ. The gate of the transistor finger 102ᵢ might be connected to the control signal node 110.

Unit cell 402ᵢ also includes a first contact 202ᵢ and a second contact 204ᵢ. Similarly to unit cells 402₀ and 402₁, the second contact 204ᵢ might be connected to the second segment 104bᵢ to connect one side of the source-drain path (e.g., drain) of the transistor finger 102ᵢ to the high-voltage node 106 connected to the circuit to be discharged. In this embodiment, the second contact 204ᵢ might be connected to the second segment 104bᵢ such that the entire second segment 104bᵢ is floating. The first contact 202ᵢ might be connected to the first segment 104aᵢ to connect the other side of the source-drain path (e.g., source) of the transistor finger 102ᵢ to the reference voltage node 108. In this example, however, to compensate for resistance 404, the first contact 202ᵢ might be connected to the first segment 104aᵢ such that a first part of the first segment 104aᵢ as indicated at 206ᵢ is connected between the first contact 202ᵢ and one side of the source-drain path (e.g., source) of the transistor finger 102ᵢ and a second part of the first segment 104aᵢ as indicated at 208ᵢ is floating. The point along first segment 104aᵢ where the first contact 202ᵢ is connected may be adjusted to adjust the resistance connected between the first contact 202ᵢ and one side of the source-drain path (e.g., source) of the transistor finger 102ᵢ. In this way, the resistance connected between the first contact 202ᵢ and one side of the source-drain path (e.g., source) of the transistor finger 102ᵢ plus the resistance 404 might equal the resistance of the first segment 104a₀ of the unit cell 402₀ and the first segment 104a₁ of the unit cell 402₁ such that the discharge currents of the unit cells 402₀ to 402ᵢ are balanced.

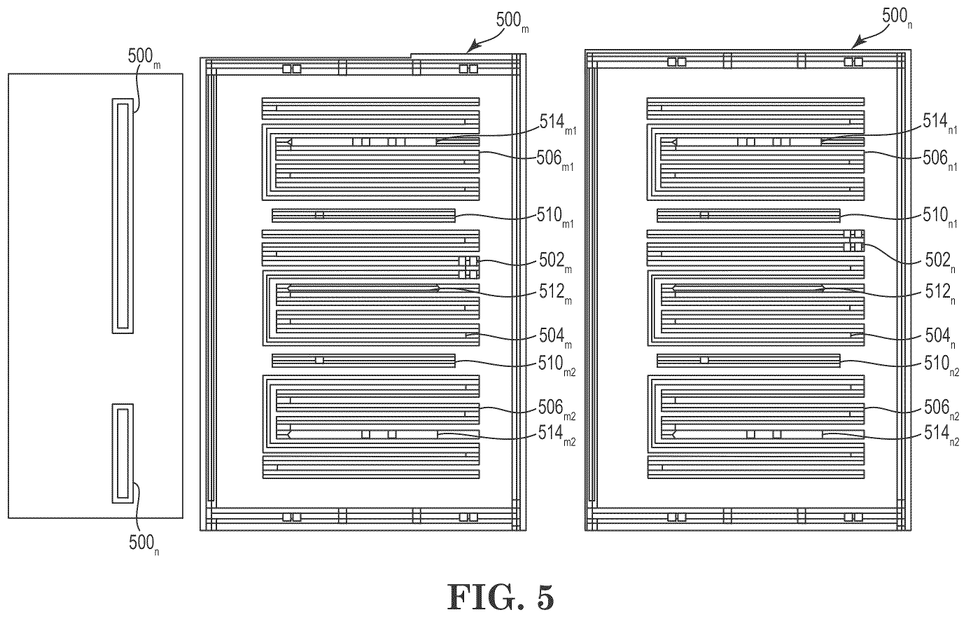

FIG. 5 is a schematic layout diagram of two banks 500ₘ and 500ₙ of unit cells of a discharge circuit according to an embodiment. A plurality of banks may be connected in parallel to provide a discharge circuit, such as discharge circuit 100a, 100b, or 100c as previously described and illustrated with reference to FIGS. 1A-1C. As illustrated on the left of FIG. 5, a larger (e.g., more unit cells) bank 500ₘ includes a first source ballast resistance value and a smaller (e.g., fewer unit cells) bank 500ₙ includes a second source ballast resistance value different from the first source ballast resistance value. The different source ballast resistance values of banks 500ₘ and 500ₙ might be used to achieve current uniformity within a discharge circuit similarly as described above with reference to FIG. 4.

As illustrated in the center of FIG. 5, each unit cell of bank 500ₘ might include two transistor fingers including gate contacts 510ₘ₁ and 510ₘ₂, a source contact 512ₘ, drain contacts 514ₘ₁ and 514ₘ₂, a reference voltage node contact 502ₘ, and metal resistor portion segments 504ₘ, 506ₘ₁, and 506ₘ₂. Gate contacts 510ₘ₁ and 510ₘ₂ might connect the corresponding gates of the transistor fingers to a control signal node 110 (FIG. 4). Source contact 512ₘ, which might be shared by both transistor fingers, might connect the source of both transistor fingers to the segment 504ₘ of the metal resistor portion. Reference voltage node contact 502ₘ might be connected to segment 504ₘ to set the source ballast resistance value of each transistor finger of bank 500ₘ. In this example, the reference voltage node contact 502ₘ is connected to segment 504ₘ such that a first part of segment 504ₘ is connected between the source contact 512ₘ and the reference voltage node contact 502ₘ and a second part of the segment 504ₘ is floating. Drain contact 514ₘ₁ might connect the drain of one transistor finger to the segment 506ₘ₁ of the metal resistor portion, and drain contact 514ₘ₂ might connect the drain of the other transistor finger to the segment 506ₘ₂ of the metal resistor portion. In this example, the drain contacts 514ₘ₁ and 514ₘ₂ might also be connected to a high-voltage node 106 (FIG. 4) such that each segment 506ₘ₁ and 506ₘ₂ is floating.

As illustrated on the right of FIG. 5, each unit cell of bank 500ₙ might include two transistor fingers including gate contacts 510ₙ₁ and 510ₙ₂, a source contact 512ₙ, drain contacts 514ₙ₁ and 514ₙ₂, a reference voltage node contact 502ₙ, and metal resistor portion segments 504ₙ, 506ₙ₁, and 506ₙ₂. Gate contacts 510ₙ₁ and 510ₙ₂ might connect the corresponding gates of the transistor fingers to a control signal node 110 (FIG. 4). Source contact 512ₙ, which might be shared by both transistor fingers, might connect the source of both transistor fingers to the segment 504ₙ of the metal resistor portion. Reference voltage node contact 502ₙ might be connected to segment 504ₙ to set the source ballast resistance value of each transistor finger of bank 500ₙ. In this example, the reference voltage node contact 502ₙ is connected to segment 504ₙ such that a first part of segment 504ₙ is connected between the source contact 512ₙ and the reference voltage node contact 502ₙ and a second part of the segment 504ₙ is floating. In bank 500ₙ, however, the resistance of the first part between the source contact 512ₙ and the reference voltage node contact 502ₙ is greater than the resistance of the first part between the source contact 512ₘ and the reference voltage node contact 502ₘ of bank 500ₘ. Drain contact 514ₙ₁ might connect the drain of one transistor finger to the segment 506ₙ₁ of the metal resistor portion, and drain contact 514ₙ₂ might connect the drain of the other transistor finger to the segment 506ₙ₂ of the metal resistor portion. In this example, the drain contacts 514ₙ₁ and 514ₙ₂ might also be connected to a high-voltage node 106 (FIG. 4) such that each segment 506ₙ₁ and 506ₙ₂ is floating.

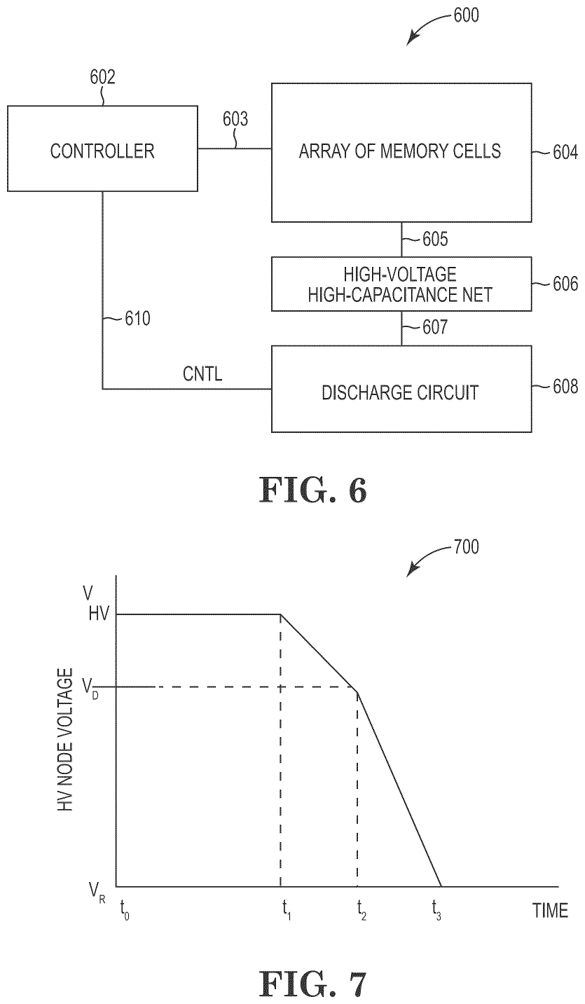

FIG. 6 is a simplified block diagram of a memory device 600 according to an embodiment. Memory device 600 includes a controller 602, an array of memory cells 604, a high-voltage (e.g., greater than 15V), high-capacitance (e.g., greater than 1 nF) net 606, and a discharge circuit 608. Controller 602 is in communication with array of memory cells 604 through a communication path 603. Controller 602 is connected to discharge circuit 608 through a control (CNTL) signal path 610. Array of memory cells 604 is connected to high-voltage, high-capacitance net 606 through a signal path 605. High-voltage, high-capacitance net 606 is connected to discharge circuit 608 through a signal path 607.

Controller 602 might include a microcontroller, a control unit (CU), a central processing unit (CPU), or other suitable logic circuitry. Controller 602 might be configured to perform access operations (e.g., read, program, and/or erase) on the array of memory cells 604 and to selectively enable the discharge circuit 608 to discharge the high-voltage, high-capacitance net 606. High-voltage, high-capacitance net 606 might be charged and discharged to perform the access operations on the array of memory cells 604. In some embodiments, the high-voltage, high capacitance net 606 might provide the high-voltage node 106 previously described and illustrated with reference to FIGS. 1A-5. Discharge circuit 608 might be configured to discharge the high-voltage, high-capacitance net 606 in response to a control signal from the controller 602 on signal path 610. In some embodiments, the discharge circuit 608 might include the discharge circuit 100a, 100b, 100c, or 400 previously described and illustrated with reference to FIGS. 1A-IC and 4, respectively. The controller 602 might be configured to enable the discharge circuit 608 and prevent snapback and remain in a safe operating area (SOA) by applying a first voltage level to the gate of the transistor 102 (FIG. 1A-1C or 4) of the discharge circuit for a first period followed by a second voltage level higher than the first voltage level for a second period.

FIG. 7 is a chart 700 illustrating the operation of a discharge circuit according to an embodiment. Chart 700 includes the voltage on the high-voltage, high-capacitance net 606 (e.g., high-voltage node 106) versus time. At time to, the high-voltage node might be fully charged to a high-voltage (V_{HV}), such as a voltage within a range between 15V and 30V. At time t₁, the discharge circuit might be enabled by applying a first voltage level to the gate of the transistor 102 (FIG. 1A-1C or 4). In response to applying the first voltage to the gate of the transistor 102, the voltage on the high-voltage node begins to discharge at a first rate as indicated between times t₁ and t₂. Once the voltage of the high-voltage node is discharged to a voltage (V_{D}) where snapback is no longer a concern, a second voltage level higher than the first voltage level might be applied to the gate of the transistor 102. The voltage V_{D} might be detected by controller 602 (FIG. 6) or based on a delay from time t₁. In response to applying the second voltage to the gate of the transistor 102 at time t2, the voltage on the high-voltage node discharges at a second rate faster than the first rate as indicated between times t₂ and t₃. At time t₃, the high-voltage node might be fully discharged to the reference voltage (V_{R}) (e.g., a common or ground voltage). In other embodiments, more than two increasingly higher voltage levels may be applied to the gate of the transistor 102 for respective predetermined periods to discharge the high-voltage node while mitigating snapback and SOA concerns.

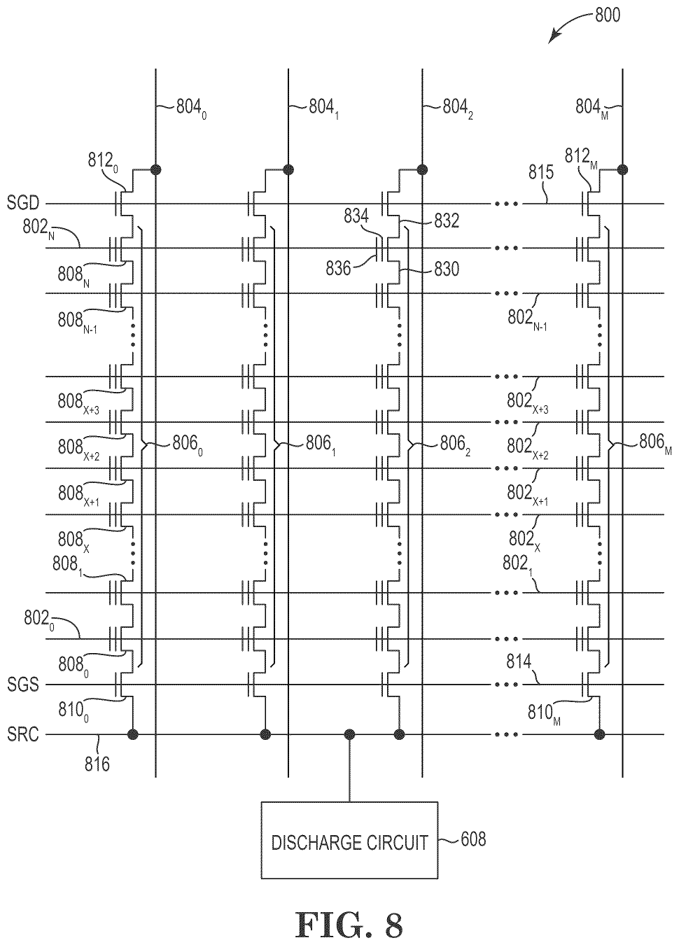

FIG. 8 is a schematic of a portion of an array of memory cells 800, such as a NAND memory array, as could be used in a memory of the type described with reference to FIG. 6, e.g., as a portion of array of memory cells 604. Memory array 800 includes access lines (e.g., word lines) 802₀ to 802_{N}, and data lines (e.g., bit lines) 804₀ to 804_{M}. The access lines 802 might be connected to global access lines (e.g., global word lines), not shown in FIG. 8, in a many-to-one relationship. For some embodiments, memory array 800 might be formed over a semiconductor that, for example, might be conductively doped to have a conductivity type, such as a p-type conductivity, e.g., to form a p-well, or an n-type conductivity, e.g., to form an n-well.

Memory array 800 might be arranged in rows (each corresponding to an access line 802) and columns (each corresponding to a data line 804). Each column might include a string of series-connected memory cells (e.g., non-volatile memory cells), such as one of NAND strings 806₀ to 806_{M}. Each NAND string 806 might be connected (e.g., selectively connected) to a common source (SRC) 816 and might include memory cells 808₀ to 808_{N}. The common source 816 might have a capacitance (e.g., parasitic capacitance) greater than 1 nF. The memory cells 808 might represent non-volatile memory cells for storage of data. The memory cells 808₀ to 808_{N} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 808 of each NAND string 806 might be connected in series between a select gate 810 (e.g., a field-effect transistor), such as one of the select gates 810₀ to 810_{M} (e.g., that might be source select transistors, commonly referred to as select gate source), and a select gate 812 (e.g., a field-effect transistor), such as one of the select gates 812₀ to 812_{M} (e.g., that might be drain select transistors, commonly referred to as select gate drain). Select gates 810₀ to 810_{M} might be commonly connected to a select line 814, such as a source select line (SGS), and select gates 812₀ to 812_{M} might be commonly connected to a select line 815, such as a drain select line (SGD). Although depicted as traditional field-effect transistors, the select gates 810 and 812 might utilize a structure similar to (e.g., the same as) the memory cells 808. The select gates 810 and 812 might represent a plurality of select gates connected in series, with each select gate in series configured to receive a same or independent control signal.

A source of each select gate 810 might be connected to common source 816. The drain of each select gate 810 might be connected to a memory cell 808₀ of the corresponding NAND string 806. For example, the drain of select gate 810₀ might be connected to memory cell 808₀ of the corresponding NAND string 806₀. Therefore, each select gate 810 might be configured to selectively connect a corresponding NAND string 806 to common source 816. A control gate of each select gate 810 might be connected to select line 814.

The drain of each select gate 812 might be connected to the data line 804 for the corresponding NAND string 806. For example, the drain of select gate 812₀ might be connected to the data line 804₀ for the corresponding NAND string 806₀. The source of each select gate 812 might be connected to a memory cell 808_{N} of the corresponding NAND string 806. For example, the source of select gate 812₀ might be connected to memory cell 808_{N} of the corresponding NAND string 806₀. Therefore, each select gate 812 might be configured to selectively connect a corresponding NAND string 806 to the corresponding data line 804. A control gate of each select gate 812 might be connected to select line 815.

The memory array in FIG. 8 might be a quasi-two-dimensional memory array and might have a generally planar structure, e.g., where the common source 816, NAND strings 806 and data lines 804 extend in substantially parallel planes. Alternatively, the memory array in FIG. 8 might be a three-dimensional memory array, e.g., where NAND strings 806 might extend substantially perpendicular to a plane containing the common source 816 and to a plane containing the data lines 804 that might be substantially parallel to the plane containing the common source 816.

Typical construction of memory cells 808 includes a data-storage structure 834 (e.g., a floating gate, charge trap, or other structure configured to store charge) that can determine a data state of the memory cell (e.g., through changes in threshold voltage), and a control gate 836, as shown in FIG. 8. The data-storage structure 834 might include both conductive and dielectric structures while the control gate 836 is generally formed of one or more conductive materials. In some cases, memory cells 808 might further have a defined source/drain (e.g., source) 830 and a defined source/drain (e.g., drain) 832. Memory cells 808 have their control gates 836 connected to (and in some cases form) an access line 802.

A column of the memory cells 808 might be a NAND string 806 or a plurality of NAND strings 806 selectively connected to a given data line 804. A row of the memory cells 808 might be memory cells 808 commonly connected to a given access line 802. A row of memory cells 808 can, but need not, include all memory cells 808 commonly connected to a given access line 802. Rows of memory cells 808 might often be divided into one or more groups of physical pages of memory cells 808, and physical pages of memory cells 808 often include every other memory cell 808 commonly connected to a given access line 802. For example, memory cells 808 commonly connected to access line 802_{N} and selectively connected to even data lines 804 (e.g., data lines 804₀, 804₂, 804₄, etc.) might be one physical page of memory cells 808 (e.g., even memory cells) while memory cells 808 commonly connected to access line 802_{N} and selectively connected to odd data lines 804 (e.g., data lines 804₁, 804₃, 804₅, etc.) might be another physical page of memory cells 808 (e.g., odd memory cells). Although data lines 804₃-804₅ are not explicitly depicted in FIG. 8, it is apparent from the figure that the data lines 804 of the array of memory cells 800A might be numbered consecutively from data line 804₀ to data line 804_{M}. Other groupings of memory cells 808 commonly connected to a given access line 802 might also define a physical page of memory cells 808. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 802₀-802_{N} (e.g., all NAND strings 806 sharing common access lines 802). Unless expressly distinguished, a reference to a page of memory cells herein refers to the memory cells of a logical page of memory cells.

During an erase operation, the data lines 804 and the common source 816 might be biased to a first voltage level (e.g., an erase voltage, such as 20V), the access lines 802 might be biased to 0V, select line 815 might be biased to a second voltage level less than the first voltage level, and the select line 814 might be biased to a third voltage level less than the first voltage level. Discharge circuit 608 might be connected to common source 816 to selectively discharge common source 816 in response to a control signal from controller 602 (FIG. 6) as previously described, such as after completing an erase operation on the array of memory cells 800.

Although the example of FIG. 8 is discussed in conjunction with NAND flash, the embodiments and concepts described herein are not limited to a particular array architecture or structure, and can include other structures (e.g., SONOS or other data storage structure configured to store charge) and other architectures (e.g., AND arrays, NOR arrays, etc.).

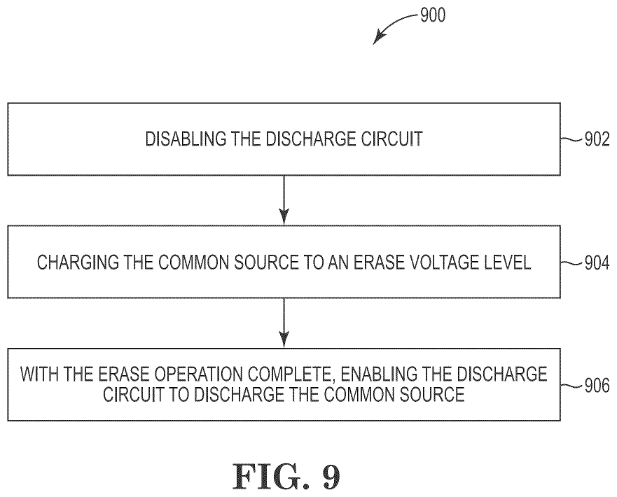

FIG. 9 is a flow diagram illustrating a method 900 for performing an erase operation on an array of memory cells according to an embodiment. Method 900 might correspond at least in part to FIGS. 1A-8. The method might be in the form of computer-readable instructions, e.g., stored in controller 602 or array of memory cells 604 of FIG. 6. Such computer-readable instructions might be executed by a controller, e.g., the controller 602, to cause the memory device 600 to perform the method. Method 900 might be implemented by a memory device 600 including a common source 816, an array of memory cells 800 connected to the common source 816, and a discharge circuit 608 connected to the common source 816 as previously described and illustrated with reference to FIGS. 6 and 8. At 902, method 900 includes disabling the discharge circuit. At 904, method 900 includes charging the common source to an erase voltage level (e.g., greater than 15V). At 906, method 900 includes with the erase operation complete, enabling the discharge circuit to discharge the common source.

### Conclusion

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments.

What is claimed is:

1. A memory device comprising:
a common source;
an array of memory cells connected to the common source; and
a discharge circuit connected to the common source, wherein the discharge circuit comprises:
a transistor comprising a plurality of unit cells; and
a metal resistor connected to the transistor, the metal resistor comprising a plurality of resistor portions corresponding to the plurality of unit cells.

2. The memory device of claim 1, wherein each unit cell of the plurality of unit cells has a footprint and a corresponding resistor portion of the plurality of resistor portions is arranged within the footprint.

3. The memory device of claim 1, further comprising:
a controller configured to perform access operations on the array of memory cells and to selectively enable the discharge circuit to discharge the common source.

4. The memory device of claim 3, wherein the controller is configured to enable the discharge circuit and prevent snapback by applying a first voltage level to a gate of the transistor for a first period followed by a second voltage level higher than the first voltage level for a second period.

5. The memory device of claim 1, wherein the metal resistor is directly connected to a source of the transistor.

6. The memory device of claim 1, wherein the metal resistor is directly connected to a drain of the transistor.

7. The memory device of claim 1, wherein each resistor portion of the plurality of resistor portions comprises a first segment directly connected to a source of the transistor and a second segment directly connected to a drain of the transistor.

8. The memory device of claim 7, wherein the discharge circuit further comprises:
a plurality of first contacts, each first contact of the plurality of first contacts connected to a corresponding first segment to connect the source of the transistor to a reference voltage node; and
a plurality of second contacts, each second contact of the plurality of second contacts connected to a corresponding second segment to connect the common source to the drain of the transistor.

9. The memory device of claim 1, wherein the memory cells comprise non-volatile memory cells.

10. A memory device comprising:
an array of memory cells comprising a plurality of strings of series-connected memory cells;
a plurality of access lines, each access line of the plurality of access lines connected to a control gate of a respective memory cell of each string of series-connected memory cells of the plurality of strings of series-connected memory cells;
a common source;
a plurality of data lines, wherein each string of series-connected memory cells of the plurality of strings of series-connected memory cells is selectively connected between the common source and a respective data line of the plurality of data lines; and
a discharge circuit connected to the common source, wherein the discharge circuit comprises:
a transistor comprising a plurality of unit cells; and
a metal resistor connected to the transistor, the metal resistor comprising a plurality of resistor portions corresponding to the plurality of unit cells.

11. The memory device of claim 10, wherein each unit cell of the plurality of unit cells has a footprint and a corresponding resistor portion of the plurality of resistor portions is arranged within the footprint.

12. The memory device of claim 10, further comprising:
a controller configured to perform an erase operation on the array of memory cells by disabling the discharge circuit, charging the common source to an erase voltage level, and with the erase operation complete, enabling the discharge circuit to discharge the common source.

13. The memory device of claim 12, wherein the erase voltage level is higher than 15V, and
wherein the common source has a capacitance greater than 1 nF.

14. The memory device of claim 10, wherein the transistor comprises a NMOS transistor.

15. The memory device of claim 10, wherein the transistor comprises a triple well NMOS transistor.

16. The memory device of claim 10, wherein the array of memory cells comprises a NAND memory array.

17. A memory device comprising:
a common source;
an array of memory cells connected to the common source; and
a discharge circuit connected to the common source, wherein the discharge circuit comprises:
a transistor comprising a first bank of first unit cells and a second bank of second unit cells; and
a metal resistor connected to the transistor, the metal resistor comprising a plurality of resistor portions corresponding to the first unit cells and the second unit cells.

18. The memory device of claim 17, wherein each unit cell of the first unit cells and the second unit cells has a footprint and a corresponding resistor portion of the plurality of resistor portions is arranged within the footprint.

19. The memory device of claim 17, wherein the first bank of first unit cells comprises more unit cells than the second bank of second unit cells.

20. The memory device of claim 17, wherein the first bank and the second bank are connected in parallel.
